(19) United States
(12) Patent Application Publication
(10) Pub. No.: US 2013/0049884 A1
(43) Pub. Date: Feb. 28, 2013

(54) METHODS AND CIRCUITS FOR ATTENUATING HIGH-FREQUENCY NOISE

(71) Applicants: Kevin Patrick Lavery, Sugar Land, TX (US); Pravin P. Patel, Sugar Land, TX (US)

(72) Inventors: Kevin Patrick Lavery, Sugar Land, TX (US); Pravin P. Patel, Sugar Land, TX (US)

(73) Assignee: TEXAS INSTRUMENTS INCORPORATED, Dallas, TX (US)

(21) Appl. No.: 13/214,749

(22) Filed: Aug. 22, 2011

(51) Int. Cl. H03H 7/00

(52) U.S. Cl. 333/172; 333/167

(57) ABSTRACT

Low-frequency digital data input signals in an integrated circuit are controlled between first and second stages in a signal input path of the integrated circuit by a capacitance in the signal input path between the first and second stages. The capacitance is sized to attenuate high-frequency noise in the signal input path. In one embodiment, the integrated circuit may be an input buffer circuit in which the capacitance is a capacitor between the signal input path and a reference potential, a voltage source, or both. In another embodiment, the integrated circuit may be an oscillator circuit in which the capacitance is provided between corresponding elements of a differential pair of transistors in the first stage.

### FIELD

The various circuit embodiments described herein relate in general to high-frequency noise attenuating circuits and methods, and more particularly high-frequency noise attenuating circuits and methods of the type described, used in single and dual-ended input buffer circuits and extensions thereof.

### BACKGROUND

Typical microcontroller devices, or the like, may have input buffer circuits to condition the control and low-frequency digital data input signals to the device. However, the control and low-frequency digital data input signals can be disturbed by high-frequency noise. The noise may be, for instance, the result of noise bursts, or may be continuous. As a result, the input signals may not accurately be reproduced, resulting in degradation in performance of the device.

In the past, in order to improve the immunity of input buffer circuits to the effects of such high-frequency noise, one or more resistor-capacitor combinations have been used on the PCB before the first stage of the input buffer; it is also possible to incorporate these resistor-capacitor combinations inside the device prior to the first stage of the input buffer. An example of a two-stage input buffer circuit 10 that has been proposed is shown in FIG. 1. The input buffer circuit 10 has an input stage 12 and an output stage 14, each having complementary MOS transistors connected between a supply rail 16 and a reference potential 18. The output from the input stage 12 is directly connected to the input of the output stage 14, which produces an output signal on output line 19.

Resistor/capacitor combinations 20 and 22 are connected in front of the input stage 12. The resistor/capacitor combination 20 has a resistor R1 connected between the input line 26 and the gate of a PMOS device P1 and a capacitor C1 connected between the gate of the PMOS device P1 and the supply rail 16. The resistor/capacitor combination 22 has a resistor R2 connected between the input line 26 and the gate of an NMOS device N1 and a capacitor C2 connected between the gate of the NMOS device N1 and the reference potential 18.

In the implementation of the circuit 10, in order to filter the high-frequencies of interest, the resistors and/or capacitors R1, R2, C1 and C2 need to be relatively large. Moreover, because the capacitors C1 and C2 on the gates of the PMOS device P1 and the NMOS device N1 of the input stage 12 are relatively large, they have the effect of slowing down the input signal. Therefore, the overall performance of the input buffer 10 is degraded from its ideal performance if it were in a noiseless environment. Moreover, because the input signal is slowed down, the input buffer 10, itself, needs to be designed to be as fast as possible to compensate for the slowed input signal.

High-frequency noise creates problems in other circuits, as well. For example, in oscillator circuits, very high-frequency noise often may be capacitively coupled at the input, causing unexpected responses in the oscillator circuitry.

What is needed is an effective method and circuitry to control very high-frequency noise and circuitry using same that does not require large resistances and capacitances, that does not unduly slow down the operation of the circuits, and that can easily be included in modern integrated circuit topologies.

### SUMMARY

Examples of two circuit embodiments are described. In the single-ended input buffer example, a small amount of capacitance is added after the first stage of the signal input path. The on-resistance of the first stage along with the additional capacitance forms a low pass filter in the input buffer. By placing the capacitance between the first and subsequent stages, the input waveform is undisturbed by high-frequency noise to which the circuit may be subjected.

In the differential-input buffer (within the forward path (into the device) of an oscillator) example, a capacitance is added between the nodes of the opposite sides of the comparator. This capacitance is added after the PMOS buffer and maintains the opposite sides at an equipotential at high-frequencies while allowing the desired signal to toggle the comparator. Thus, the output of the amplifier is kept from toggling due to the high-frequency noise.

According to one example of a method described herein, low-frequency digital data input signals are controlled in an integrated circuit. First and subsequent stages are provided in a signal input path of the integrated circuit. A capacitance is provided in the signal input path between the first and subsequent stages. The capacitance is sized to attenuate high-frequency noise in the signal input path. In one embodiment, the integrated circuit may be a single-ended input buffer circuit (in this case, a digital input pin) in which the capacitance is a capacitor between the signal input path and a reference potential, a voltage source, or both. In another embodiment, the integrated circuit may be a differential input (in this case within an oscillator circuit) in which the capacitance is provided between corresponding elements of a differential pair of transistors or a capacitance from each/either leg of the differential pair to ground or by reducing the pmos gain and adding capacitance in any of these places.

According to an example of a single-ended input buffer circuit, first and subsequent buffer stages in a signal input path has a capacitance in the signal input path and after the first stage of the input buffer to attenuate high-frequency noise in the input path. The capacitance forms a low pass filter in combination with resistances of the first buffer stage. The capacitance may be a capacitor connected between an output of the first stage of the input buffer and a reference potential, a supply voltage, or both.

According to an example of a differential input circuit, a differential pair of transistors operative to toggle in response to an oscillator input signal is provided. A pair of current mirrors mirror the currents in the differential pair of transistors, one of the current mirrors providing an output voltage. At least one capacitance is provided from at least one output node of said differential pair of transistors, the capacitance being sized to bypass noise frequencies.

### BRIEF DESCRIPTION OF THE DRAWINGS

FIG. 1 is an electrical schematic diagram of an input buffer using conventional RC networks in front of the first stage of the buffer.

FIG. 2 is an electrical schematic diagram of an embodiment of an input buffer using a capacitance after the first stage of the input buffer to attenuate high-frequency noise.

FIG. 3 is an electrical schematic diagram of an embodiment of a differential input (in this case, within an oscillator) using a capacitance between output nodes of a differential pair of transistors for sensing an oscillator input signal to attenuate high-frequency noise.

In the various figures of the drawing, like reference numbers may be used to denote like or similar parts.

### DETAILED DESCRIPTION

According to an embodiment of a method for reducing the effects of high and very-high-frequency noise, a small amount of capacitance is added after the first stage of the signal input path in the circuit that is to be protected from the noise. The on-resistance of the first stage along with the additional capacitance forms a low pass filter. By placing the capacitance at this point, the output waveform is undisturbed by the noise to which the circuit may be subjected.

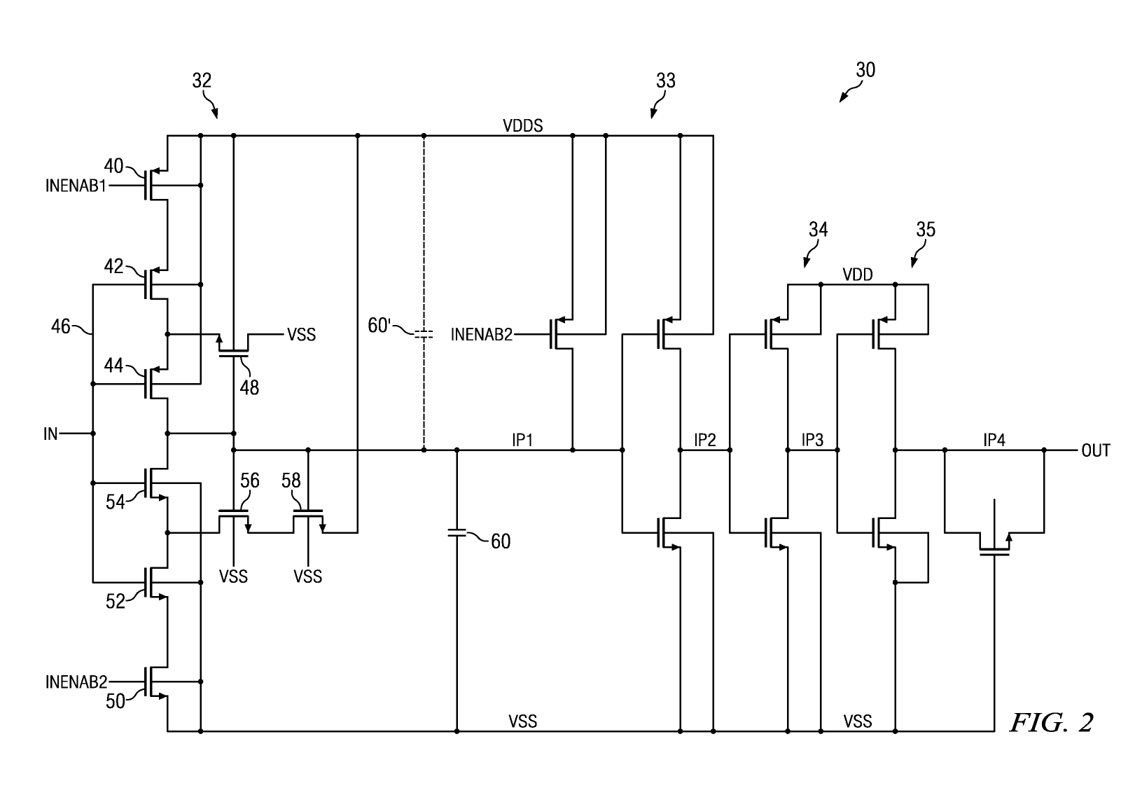

This is illustrated in the electrical schematic diagram of FIG. 2 to which reference is now made, showing an embodiment of an input buffer 30. The input buffer 30 in the embodiment illustrated has first, second, third, and fourth stages 32-35, respectively.

The first stage 32 has a string of PMOS devices 40, 42, and 44 connected between the supply voltage VDDS and a first stage output line IP1. The gates of the PMOS devices 42 and 44 are connected to receive the input signal on the input line 46. The gate of the PMOS device 40 receives an enable signal, INENAB1. A fourth PMOS device 48 is connected between the reference potential VSS and the source of the PMOS device 44. Thus, when enabled by the signal INENAB1 and when the input signal on line 46 goes low, below the threshold of PMOS devices 42 and 44, the first stage output line IP1 is pulled up to the supply voltage VDDS.

The first stage 32 also has a string of NMOS devices 50, 52, and 54 connected between the reference potential VSS and the first stage output line IP1. The gates of the NMOS devices 52 and 54 are connected to receive the input signal on the input line 46. The gate of the NMOS device 50 receives an enable signal, INENAB2. Fourth and fifth NMOS device 56 and 58 are serially connected between the supply voltage VDDS and the source of the NMOS device 54. Thus, when enabled by the signal INENAB2 and when the input signal on line 46 goes high, above the threshold of NMOS devices 52 and 54, the first stage output line IP1 is pulled down to the reference potential VSS, under the influence of the hysteresis created at least in part by the PMOS device 48 and NMOS devices 56 and 58.

A capacitor 60 is connected to the first stage output line IP1. In the embodiment illustrated, the capacitor 60 is connected to the reference potential VSS; however, in other embodiments a capacitor 60′ may be connected to the supply voltage VDDS, or other appropriate location. In still other embodiments, the capacitance may be provided by a first capacitor 60 connected between the output line IP1 and the reference potential VSS and a second capacitor 60′ connected between the output line IP1 and the supply voltage VDDS. In any event, the capacitance provided by the capacitor 60 can be small, for example, about 100 femtofarads, because the various MOS circuit elements provide a sufficiently high resistance to enable the small capacitor 60, in conjunction with the MOS resistance, to form a suitable low pass filter. Thus, one of the advantages of placing the capacitor in this location is that the size of the capacitor needed can be made small, due to the large on-resistance of the first buffer stage.

The particular size of the capacitor 60 needed for a particular application may be determined on a case-by-case basis. However, the parameters of the particular circuit may be estimated through, for example, a SPICE simulation, and the noise frequencies may be estimated by simple noise measurements. Consequently, the particular size of the capacitor 60 can be easily estimated, an estimation itself being sufficient in many implementations. It is also possible to add a low-resistance switch in series with the capacitors in order to allow the frequency range of the filter to be controlled from an input port.

It should be noted that the input signal on the first stage output line IP1 may be previously unfiltered. However, due to the low pass filter after the first stage 32, the high and very high-frequency noise nevertheless can be effectively filtered, without the need for large resistors and capacitors on the input side of the first stage 32. Moreover, the low gain of the first buffer provides an ideal place to perform the filtering action of the added capacitor.

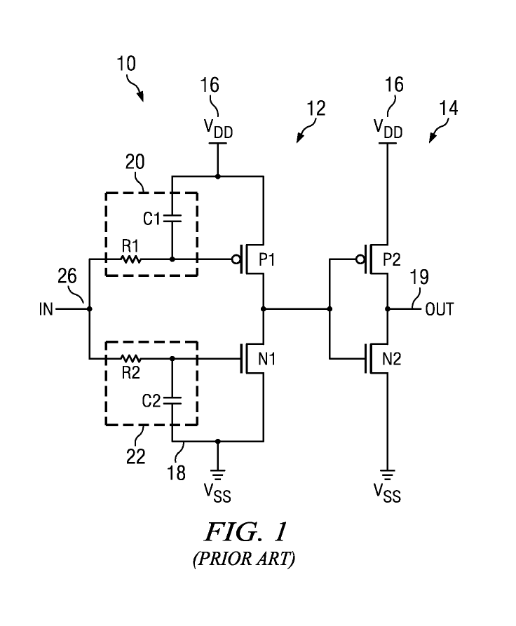

Because of the small size of the capacitor that is needed to effectively eliminate the high- and very high-frequency noise, if the buffer is strong, the speed of the circuit may be only minimally affected, compared to the speed impact on the circuit in which the resistor-capacitor combinations are employed in front of the first stage of the input buffer 10 of the type shown in FIG. 1. On the other hand, if the buffer is weak, the small capacitance may slow the input propagation, but it has little effect on the signal on the input. Nevertheless, the capacitor 60 has the effect of slowing down the buffer somewhat so that it does not respond to the noise component on the signal being amplified. Thus, the drive to make the input buffer 32 as fast as possible can be relaxed, compared to circuits in which the resistor-capacitor combinations are employed in front of the first stage of the input buffer. The placement of the capacitor after the first buffering stage means that the action of the capacitance slows neither the input waveform nor the corresponding output. Thus, this solution may be used in a bi-directional buffer implementation, if desired.

The filtered signal on the first stage output line IP1 is applied to the subsequent stages 33-35 to provide an amplified and filtered output signal on output line IP4.

Although consideration might be given to placing the capacitor 60 on the output, OUT, of the input buffer circuit 30, is should be noted that at the location on line IP1 illustrated, immediately following the first stage 32, the signal is still analog in character. That is, absent the solution proposed herein, the rise/fall characteristics of the input (along with any input noise) are maintained. As the signal is amplified, the rise/fall edges are sped up so that the waveform is squared. This “squaring up” adds high frequency components to the waveform so that the high-frequency noise elements are more difficult to filter. At the output, OUT, the signal is largely digital with higher frequency components adding high-frequency content. Output filtering, therefore, would require significantly more design considerations to remove the noise component. Thus, by including the capacitor 60 at the location shown, the unwanted high frequency components are removed before the signal is squared-up.

It can therefore be seen that the noise rejection solution is simple and small. The input signal is buffered prior to the capacitance 60, so that circuit changes have little or no impact on the input waveform. Unlike glitch filters which respond only to noise bursts and which can alias for high-frequencies, this solution will not alias and, in fact, can also be used in conjunction with a digital glitch filter, or the first stage filtering could be replicated to add serial filters.

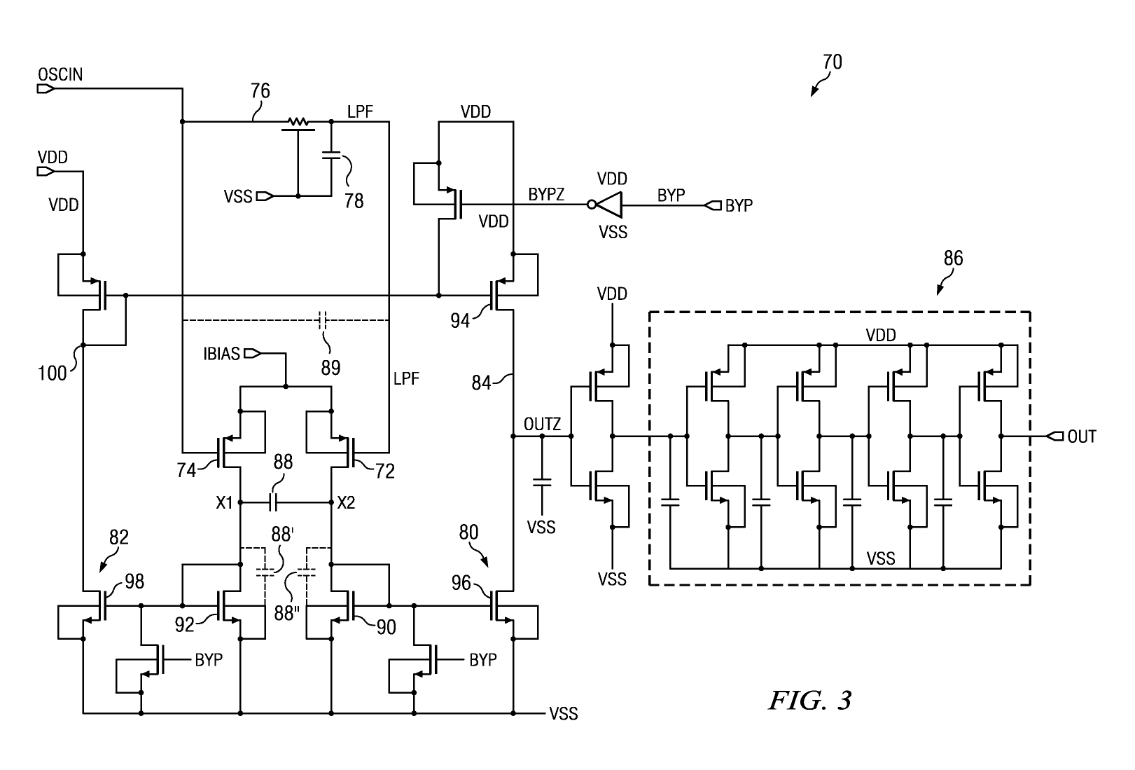

Another circuit embodiment in which the internal capacitor noise filtering technique may be used is in a differential input. The differential input structure may be used in many different circuits, one example of which is as an oscillator input circuit, an illustration of which is shown in FIG. 3, to which reference is now made. It should be noted although an oscillator embodiment is illustrated, the use of the differential input structure is not intended to be limited thereto, and a myriad of other circuits in which the differential input circuit may be advantageously employed will be apparent to those skilled in the art.

The differential input circuit 70 of FIG. 3 is of typical construction, having a first stage that includes a differential pair of transistors 72 and 74 that buffer the differential input. The current mirroring serves as a comparator to toggle according to the input signal on line 76. In the specific oscillator circuit for which this differential input circuit is used, an integrator 78 may be provided to provide an average voltage as a reference for comparison, in known manner, as shown.

The output current flowing through the differential pair of transistors 72 and 74 is detected in a second stage by respective current mirror circuits 80 and 82, the output OUTZ being derived on line 84. The output, OUTZ, is applied to a series of filter and shaping circuits 86 to produce an oscillator output, OUT.

In operation, the circuit compares the waveform on input line 76 to its integrated (average) value. The integrator 78 establishes a reference voltage on the gate of the PMOS device 72, thereby establishing a reference voltage against which the input 76 is compared. The differential pair of transistors 72 and 74 divides the current IBIAS in proportion to the voltage applied to their respective gates. The current flows through NMOS load transistors 90 and 92, developing voltages on their respective drains. Assuming the input voltage OSCIN on line 76 is higher than the voltage on the gate of device 72, the PMOS device 72 will conduct more current than device 74. The voltage on the node X1 will fall relative to the voltage on X2. (In the extreme, the voltage on node X1 falls to a threshold voltage above the reference potential VSS.) The NMOS device 98 will conduct more weakly than NMOS device 96. (In the extreme case, device 98 is placed on the threshold of conduction and is turned off). As device 98 conducts more weakly, the voltage on node 100 increases, which in turn decreases the current through device 94. (In the extreme, node 100 is pulled up to a threshold voltage below VDD, in turn, turning off PMOS device 94.) Thus, with device 96 conducting strongly and device 94 conducting weakly, the output node OUTZ 84 is pulled down.

As the input signal OSCIN decreases below the voltage of the gate of device 72, the PMOS device 72 will conduct less current than device 74. The voltage on the node X1 will rise relative to the voltage on X2. (In the extreme, the voltage on node X1 rises to an IBIAS voltage.) The NMOS device 98 will conduct more strongly than NMOS device 96. (In the extreme case, device 98 is fully turned on). As device 98 conducts more strongly, the voltage on node 100 decreases, which in turn increases the current through device 94. (In the extreme, node 100 is pulled down to a threshold voltage above VSS, in turn, turning on PMOS device 94.) Thus, with device 96 conducting weakly and device 94 conducting strongly, the output node OUTZ 84 is pulled high.

Consequently, if high frequency noise asymmetrically appears on nodes X1 or node X2, one of the mirror transistors 96 or 98 may conduct, when it shouldn't, thereby toggling the output OUTZ on line 84. If the noise is symmetrical, i.e., if the same amount of noise appears on both X1 and X2, there is no voltage difference created between the nodes, and the mirror circuit will not toggle.

Thus, in order to decrease the susceptibility of the oscillator 70 to high-frequency noise, a capacitor 88 is provided between the nodes X1 and X2 at the drains of respective differential pair transistors 72 and 74. The capacitor 88 effectively holds the nodes X1 and X2 at substantially the same potential at the noise frequencies of interest, thereby preventing the noise from toggling the comparator provided by the differential pair transistors 72 and 74.

The capacitor may be located at other strategic locations, as well, the goal being to hold the nodes X1 and X2 at substantially the same potential at the noise frequencies that may cause the comparator to toggle. For example, a capacitor 88′ may be connected between the node X1 and the reference potential. A capacitor 88″ may be connected between the node X2 and the reference potential. Alternatively, both capacitors 88′ and 88″ may be simultaneously employed, with, or without the addition of capacitor 88. Additionally, the series resistance provided by the PMOS devices 72 and 74 may be increased, for example, by reducing the size of the PMOS devices 72 and 74 in order to reduce the sensitivity of the comparator to high frequency noise.

In contrast to the addition of capacitors 88 and/or 88′ and/or 88″, which serve to filter out the high frequency noise in the comparator, a capacitor 89 may be connected between the input line OSCIN and the line LPF to add high frequency noise between the lines. That is, any noise that exists on either the input line OSCIN or the low pass filter line LPF is equally applied to the other line, hence to the gates of the PMOS devices 72 and 74. The likelihood that the comparator will toggle because of the presence of the high frequency noise is reduced.

In any event, the capacitance provided by the capacitor 88 can be small, for example, about 400 femtofarads, because the various MOS circuit elements provide a sufficiently high resistance to enable the small capacitor 88, in conjunction with the MOS resistances, to form a suitable low pass filter. The particular size of the capacitor 88 needed for a particular implementation may be determined on a case-by-case basis. However, the parameters of the particular circuit may be estimated through, for example, a SPICE simulation, and the noise frequencies may be estimated by simple noise measurements. Consequently, the particular size of the capacitor 88 can be easily estimated, an estimation itself being sufficient in many implementations. Thus, the size of the capacitor 88 can be determined based upon the noise frequencies of concern in the particular application of interest. Taken with the resistance of the oscillator circuit itself at nodes X1 and X2, the capacitor 88 effectively provides a low pass filter that allows high-frequency noise to pass, affecting both nodes X1 and X2 equally, thereby nullifying the effects of the noise. It is also possible to add a low-resistance switch in series with the capacitors in order to allow the frequency range of the filter to be controlled from an input port.

In the circuit embodiments illustrated, simulations show that noise is significantly attenuated from about 125 MHz, and is effectively removed above about 500 MHz. One of the advantages achieved by the filtering embodiments described herein is that smaller capacitor structures may be employed compared to the required capacitor sizes of previous noise filtering arrangements. The filtering action of the capacitor filters described actually improves at high-frequencies. This is convenient, because noise couples to smaller circuit elements at high-frequencies and the circuit is more efficient at the high-frequencies of interest.

It should be noted that although the capacitors 60, 60′, 88, 88′, and 88″ are shown as traditional capacitor elements, they may capacitance provided thereby may be accomplished using various components. For example, in addition to traditional capacitor elements, the capacitances can be provided by other circuit elements, such as transistors, MOS devices, or the like.

Electrical connections, couplings, and connections have been described with respect to various devices or elements. The connections and couplings may be direct or indirect. A connection between a first and a subsequent electrical device may be a direct electrical connection or may be an indirect electrical connection. An indirect electrical connection may include interposed elements that may process the signals from the first electrical device to the subsequent electrical device.

It will be appreciated that the methods and circuits described herein attenuate high-frequency noise and makes the circuits significantly more robust in noisy environments. Although the invention has been described and illustrated with a certain degree of particularity, it should be understood that the present disclosure has been made by way of example only, and that numerous changes in the combination and arrangement of parts may be resorted to without departing from the spirit and scope of the invention, as hereinafter claimed.

1. A method to control low-frequency digital data input signals in an integrated circuit, comprising:
providing a first stage in a signal input path of said integrated circuit;
providing a subsequent stage in said signal input path of said integrated circuit;
providing a capacitance in said signal input path between said first and subsequent stages, said capacitance being sized to attenuate high-frequency noise in said signal input path.

2. The method of claim 1 wherein said capacitance forms a low pass filter in combination with resistances existing in said integrated circuit.

3. The method of claim 1 wherein said integrated circuit is an input buffer circuit, and wherein said providing a capacitance comprises providing a capacitor between said signal input path and a reference potential.

4. The method of claim 1 wherein said integrated circuit is an input buffer circuit, and wherein said providing a capacitance comprises providing a capacitor between said signal input path and a supply voltage.

5. The method of claim 1 wherein said integrated circuit is an input buffer circuit, and wherein said providing a capacitance comprises providing a first capacitor between said signal input path and a reference potential and providing a second capacitor between said signal input path and a reference potential.

6. The method of claim 1 wherein said integrated circuit is an oscillator circuit, and wherein said providing a capacitance comprises providing a capacitor between corresponding elements of a differential transistor pair in said first stage.

7. The method of claim 6 wherein capacitor is sized to maintain said elements of said differential transistor pair at an equipotential level at noise frequencies to be attenuated.

8. An input buffer, comprising:
a first buffer stage in an input path of said input buffer;
a second buffer stage in said input path of said input buffer;
a capacitance in said input path and after said first stage of said input buffer to attenuates high-frequency noise in said input path.

9. The input buffer of claim 8 wherein said capacitance forms a low pass filter in combination with resistances of said first and second buffer stages.

10. The input buffer of claim 8 wherein said capacitance is a capacitor connected between an output of said first stage of said input buffer and a reference potential.

11. The input buffer of claim 8 wherein said capacitance is a capacitor connected between an output of said first stage of said input buffer and a supply voltage.

12. The input buffer of claim 8 wherein said capacitance is a first capacitor connected between an output of said first stage of said input buffer and a reference potential and a second capacitor connected between an output of said first stage of said input buffer and a supply voltage.

13. The input buffer of claim 8 wherein said capacitance is about 100 femtofarads.

14. A differential input circuit, comprising:
a differential pair of transistors operative to toggle in response to a differential input signal;
a pair of current mirrors to mirror currents in said differential pair of transistors, one of said current mirrors providing an output voltage;
and at least one capacitance from at least one output node of said differential pair of transistors, said at least one capacitance being sized to substantially equalize potentials generated by noise frequencies between outputs of said differential pair of transistors.

15. The differential input circuit of claim 14 wherein said at least one capacitance at a location selected from the group consisting of: corresponding elements of said differential pair of transistors, an output node of one of said differential pair of transistors and a reference potential, and output nodes of both of said differential pair of transistors and a reference potential.

16. The differential input circuit of claim 14 wherein capacitance capacitor sized to maintain said corresponding elements of said differential transistor pair at an equipotential level at noise frequencies to be attenuated.

17. The differential input circuit of claim 14 wherein said capacitance forms a low pass filter in combination with resistances existing in said oscillator circuit.

18. The differential input circuit of claim 14 wherein said differential pair of transistors is MOS transistors, and said corresponding elements are drain elements of respective ones of said differential pair of transistors.

19. The differential input circuit of claim 14 wherein said noise frequencies are above about 125 MHz and wherein said capacitance is about 400 femtofarads.

20. The differential input circuit of claim 14 wherein said differential input circuit is an input circuit of an oscillator circuit.
